(19) United States
(12) Patent Application Publication
(10) Pub. No.: US 2008/0116935 A1
(43) Pub. Date: May 22, 2008

(54) Source-coupled differential low-swing driver circuits

(76) Inventor: Rajendran Nair, Gilbert, AZ (US)

Correspondence Address: Rajendran Nair;ComLSI Inc., 3838 E. Encinas Ave., Gilbert, AZ, 85234, US

(21) Appl. No.: 11/601,514

(22) Filed: Nov. 20, 2006

(51) Int. Cl. H03K 19/0185

(52) U.S. Cl. 326/83

(57) ABSTRACT

A novel source-coupled differential driver circuit fully compatible with digital visual interface TMDS signaling specification is disclosed. Driven output signals are connected to the source terminals of driving switches in the invention circuit, minimizing the detrimental impact of miller coupling capacitance between gate nodes and driven output nodes upon output slew-rate, enabling higher frequencies of operation. Output signal undershoots and overshoots are also mitigated by the invention driver circuit due in part to the in-phase relationship of the gate node to the driven output node of a driver switch. Overall link performance is significantly enhanced by this SCDL driver architecture due to improved slew rates and signal integrity.

### TECHNICAL FIELD OF THE INVENTION

Embodiments of the invention relate to electronic circuitry commonly employed to transmit data and clock in the form of binary signals over lengths of interconnect to other electronic circuits, devices and systems. Such circuitry falls under the category of Data Communication Circuits.

### BACKGROUND & PRIOR ART

Low Voltage Differential Signaling (LVDS) is ubiquitous in the art. The popularity of this signaling technique arose in part from the expectation of substantially reduced power consumption because of the low (˜350 mV) swing on the lines as well as the differential nature of the signals that enabled accurate recognition despite static or dynamic variations in ground or supply voltages between the transmitting and receiving systems. Low signal swing also permits faster signal transitions, enabling higher rates of data transmission. Additionally, the differential and low-swing nature of signals also minimizes electromagnetic interference (EMI) and emissions from the signaling interconnect. Hence LVDS became the signaling method of choice for point-to-point links such as high-speed links between peripheral components of a computing system (USB), networking interconnect infrastructure installed in buildings (Ethernet) etc.

Another low-swing signaling link promoted by an industry working group (Digital Display Working Group) is the Digital Video Interface specification [DVI, reference 1]. This specification details a method for data communication between a digital video content device and a digital video display device; the specification is supported by a number of companies in the industry with compliant components. DVI 1.0 specifies the use of Transition Minimized Differential Signaling (TMDS) intended to reduce electro-magnetic emissions from the data link by reducing the number of binary transitions. The voltage swing is also minimized to approximately 500 mV on each wire of the differential pair. A typical TMDS driver is shown in FIG. 1.

TMDS uses low-swing signals, but is not necessarily low-power since the terminating voltage employed, as defined in DVI 1.0, is 3.3V. In order to produce a 500 mV swing across a 50 Ohm terminating resistor at the far end of the link, the minimum current required is 10 mA. TMDS is not truly differential in action, since current flow is only activated on one wire of the differential wire pair at any time. For example, with reference to FIG. 1, when switch S1 is activated, S2 is turned ‘off’, and a current corresponding to the current-source Is flows in terminating resistor R1. Due to strong coupling between the wires of the differential wire pair, a ‘return’ or complimentary current is induced in the wire connecting between switch S2 and terminating resistor R2 that charges the inactive complimentary wire up to AVCC. Since the voltage source feeding currents into the differential wires is at the far end of the link, and the driver drives at the near end with a current source to ground, the DC current loop is completed through the shield of the link cable. Additionally, there is signal current flow in the shield based upon coupling, or differences in coupling, of the differential pair wires to the cable shield. These are undesirable characteristics of DVI electrical and physical layers and TMDS that necessitate high quality and associated cost in video cable construction in order to maintain acceptable bit error rates.

Prior art TMDS CMOS drivers as illustrated in FIG. 1 have significant functional disadvantages that impact output signal integrity. Firstly, pull-down action through the NFET switch device is accomplished by the input gate control signal going high. The parasitic drain to gate capacitance (called a ‘miller’ coupling cap for coupling from a circuit output port to an input port) induces a voltage swing going high at the drain of the NFET before the current source current depletes the charge and develops a lower voltage at the drain node. This leads to a slower overall ‘slew-rate’ or rate of change of the output, limiting high-speed performance. Additionally, the miller cap charge and discharge in combination with device packaging parasitic elements leads to overshoots and undershoots in the differential signal developed in the output signal pair. Also, the transition of the input differential signals to the current-steering switches connected at their sources to the constant current-source modulates this current to an extent, further impacting signal integrity. An improved driver circuit is therefore necessary.

### INVENTION SUMMARY

The invention improves upon prior art substantially through a novel source-coupled differential low-swing (SCDL) driver circuit. Output signals are connected to the source terminals of driving switches in the invention circuit, minimizing the detrimental impact of miller coupling capacitance between gate nodes and driven output nodes upon output slew-rate, enabling higher frequencies of operation. Output signal undershoots and overshoots are also mitigated by the invention driver circuit due in part to the in-phase relationship of the gate node to the driven output node of a driver switch. A cascoded current source additionally ensures very high output impedance and mitigates current modulation. Due in part to the controlled output slew, the SCDL driver lends itself to transmitter emphasis, extending the reach of DVI links.

### BRIEF DESCRIPTION OF THE FIGURES

FIG. 1 illustrates a typical prior art TMDS driver and termination circuit architecture.

FIG. 2 is an illustration of the invention SCDL driver circuit and termination.

FIG. 3 is an alternate embodiment of the invention including transmitter emphasis.

FIG. 4 is an alternate embodiment of the invention developing ground-referenced far-end differential voltage swing.

### DETAILED DESCRIPTION

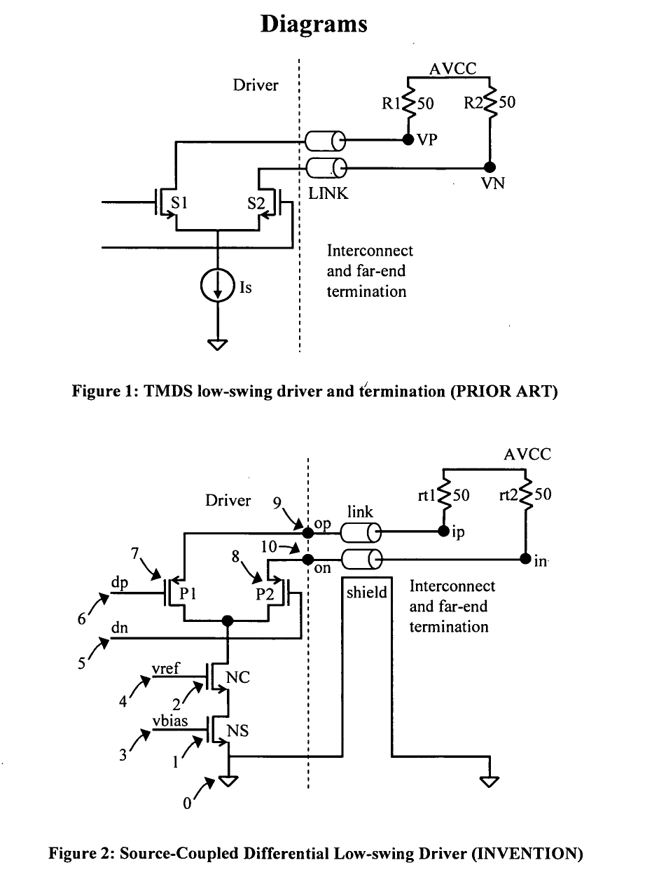

A prior art embodiment of a TMDS differential signaling output driver and termination architecture is illustrated in FIG. 1. In this driver implemented in CMOS technology, a tail current source connects through two NFET switch devices to output signal wires which are terminated at the far-end of the cable in a single-ended manner to a common reference power supply AVCC. When switch S1 turns ‘off’ and S2 turns ‘on’ driven by input signals to the gates of these devices, the current source current Iₛ is diverted to flow through the output signal wire connecting to far-end node VN and through terminating resistance R2, thereby pulling node VN lower by a voltage value corresponding to the product of the current and the terminating resistance. In typical embodiments of the prior art, the terminating resistors are 50 Ohms in value and the current source is 10 mA, resulting in a 500 mV drop in voltage. Simultaneously, since switch S1 turns ‘off’, no current flows through the output signal wire connecting to far-end node VP, and this signal wire charges up to the reference voltage AVCC. The close electromagnetic coupling between the two output wires (they are designed as a pair to present 100 Ohms characteristic impedance) ensures that the current flow activated in one signal wire induces an opposite current flow in the companion wire, thus ensuring a degree of differential current flow, diminishing radiated energy from the wires through cancellation of external fields.

An issue with the prior art driver is that the switch devices in the driver circuit are relatively large, and possess significant parasitic capacitances that impact output signal integrity. With reference to FIG. 1, the gate to drain capacitance of switch S2 conveys a portion of the activating signal that turns S2 ‘on’ to the drain node, thus yanking the drain node high by a fraction of the signal transition that activates switch S2. This is the ‘miller’ coupling capacitance effect, where the output signal feeds through to the input, or in this instance, the input signal feeds through to the output based upon the impedance presented by the output node. Since the output signal tends to go in the opposite direction to the input signal in this prior art driver, this effect is detrimental to output signal development. With reference to FIG. 1, as S2 turns on, the drain node of the switch pulls up for a short duration before coming back down because of the pull of the current source current Is. The output signal development is therefore slowed down, slowing the output ‘slew-rate’, and is non-monotonic. This behavior manifests itself in the form of voltage overshoots and undershoots, a topic specifically addressed in the DVI 1.0 specification through limits defined for this overshoot and undershoot.

Such electrical phenomena lead to lower link performance in two distinct ways. One, the slower slew rate limits the maximum data transmission frequency of the link, and second, overshoots and undershoots impact signal integrity, and the integrity of the data ‘eye’, or distinctly differential data bit duration in the differential signal received, increasing bit error rates at high frequencies and over longer lengths of interconnect.

FIG. 2 shows a preferred embodiment of the invention that addresses these problems in the prior art. Rather than the stronger, faster, NFET pull-down switches, PFET switches are employed in this embodiment to alternately convey the current source current to output signal wires. Devices P1 and P2 numbered 7 and 8 respectively are the switches with activating inputs numbered 6 and 5 termed ‘dp’ and ‘dn’ respectively. The switches connect to a cascoded, high-impedance, current source formed by the series connection of devices NC and NS numbered 2 and 1 respectively connecting further to system ground or node 0. Devices NC and NS receive bias voltage VREF and VBIAS numbered 4 and 3 respectively. Bias voltage VBIAS into device NS develops a constant current source, and device NS is shielded from voltage variations by device NC biased by a constant input voltage VREF. The current source therefore remains constant irrespective of the current-steering conducted by devices P1 and P2 from and to the output signal wires ‘op’ and ‘on’ numbered 9 and 10 respectively.

The miller coupling capacitances across switches P1 and P2 in the invention embodiment assist in output signal development, since PFET devices require a negative voltage swing at their input in order to turn ON, and the output signal desired from the driver is also a negative voltage swing down from the far-end reference voltage AVCC. Similarly, a PFET switch is turned ‘off’ by the input to its gate node going high, while the output wire connecting to the switch also transitions high towards the reference voltage AVCC. This ‘in-phase’ relationship between control and output signals ensures that the energy developed by pre-driver circuits driving signal inputs 5 and 6 is conveyed through the miller capacitances to assist in the output development, thereby improving the driver's overall energy efficiency per transition. Since there is no transient reverse swing of the output signal in a symbol transition, the rate of development of the output differential is improved significantly, improving the slew rate of the outputs. Alternately, instead of improved slew rates, the PFET switch devices may be reduced in their drive strength, with a corresponding benefit in reduced power consumption in the charge and discharge of capacitance associated with these devices. Additionally, since the miller coupling effect is in phase with output signal development, the output signal develops monotonically, eliminating overshoots or undershoots and thereby improving the differential data ‘eye’.

Another advantage of the invention circuit architecture is its self-limiting action with respect to the maximum voltage swing at the output. Since PFET switches are used, and the current source employs a cascode device NC that requires a minimum voltage value at its drain node to conduct current through, the output signal cannot swing below the sum of the minimum voltage values necessary across device NC, an active switch device and the current source device NS in its saturated state. This characteristic of the circuit further damps the voltage swings at the output near the maximum swing designed, preventing any overshoot, and makes the architecture suitable for higher voltage swings that may be necessitated by longer, high-frequency links.

Whereas faster slew rates are beneficial in binary signaling from a data communications maximum frequency and signal integrity standpoint, implications to EM radiation from the link need further inspection and are beyond the scope of this invention disclosure.

It will be evident to one skilled in the art that the advantages of the invention circuit architecture translate to substantial improvements in binary data transmission, and particularly with regard to data transmission through links with significant signal loss, dispersion or crosstalk such as low-cost video transmission cables. In such applications, conforming to DVI and high-definition multimedia interface (HDMI) specifications, link lengths exceed 15 meters and are often as much as 30 meters. Signal loss is directly proportional to the frequency of operation and to length; DVI/HDMI links are expected to see significant signal degradation as frequencies increase to accommodate high-definition video and lengths increase to facilitate sharing of high-definition video between multiple displays in a building. The invention circuit architecture therefore enables further development of such video communication interfaces.

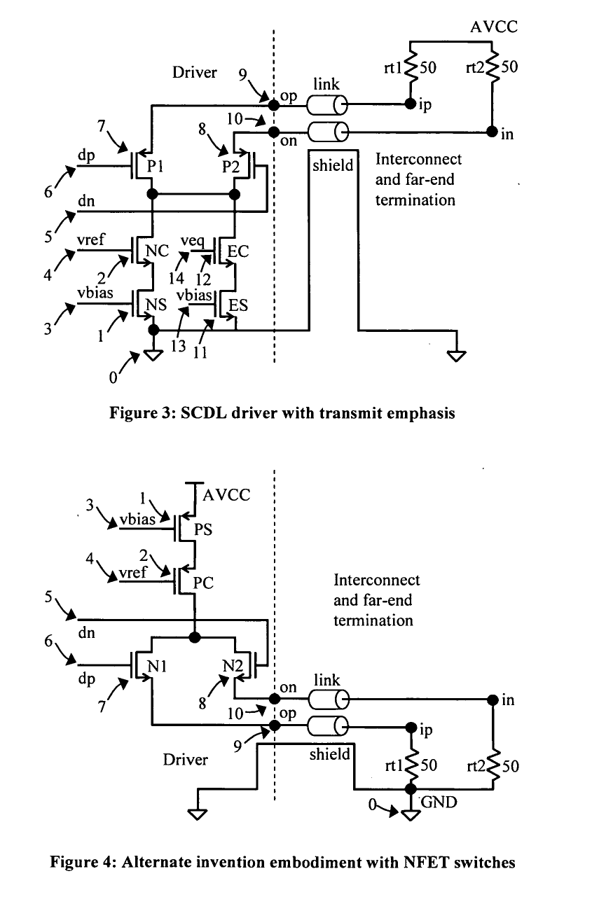

An alternate embodiment of the invention including transmitter emphasis is shown in FIG. 3. The DVI specification does not discuss this well-known technique that assists in compensating for inter-symbol interference (ISI), a common malady of lossy interconnect links transmitting binary signals at a high rate. In actuality, the overshoot and undershoot specification in the DVI document prevent the use of transmit emphasis. Nevertheless, techniques such as pre-emphasis and de-emphasis that enhance the high-frequency spectral content of transmitted data can assist in improving signal integrity and the reach of DVI cable links. The invention transmitter circuit architecture lends itself nicely to the inclusion of transmit emphasis. With reference to FIG. 3, devices 11 and 12 form an additional current source pathway controlled by signals 13 and 14, or VBIAS and VEQ respectively. In one embodiment, signal 13 is the same as signal 3, providing a bias voltage value to the current source devices NS and ES, which are also designed to conduct exactly the same current value. Signal 14, or VEQ, is controlled according to the emphasis technique implemented. In a de-emphasis implementation, signal VEQ is switched between ground and VREF depending upon the symbol sequence. When a data symbol transition (from high to low or vice-versa) occurs, both current source pathways are made active, resulting in twice the current flow and correspondingly, twice the voltage swing at the output. If the succeeding symbol is the same as its predecessor, the equalizing current pathway is disabled through signal 14 or VEQ pulled down to ground. In this manner, symbol sequences of two or more of the same value employ one-half the maximum pull-down current, while data bits with symbol transitions employ the full pull-down current. Therefore the output signal amplitude for data bits with symbol transitions is twice that for those bits that do not have a transition, as desired in simple, I-bit de-emphasis signal conditioning.

It will be evident to one skilled in the art that this transmit emphasis technique may be implemented to a finer resolution by employing additional equalizing current source branches, and by designing their values and activation control so as to provide the desired equalization function. It will also be evident that the pre-emphasis equalization technique may be similarly implemented in alternate invention embodiments.

FIG. 4 illustrates another embodiment of the invention employing NFET switches connecting to output signals in a source-coupled manner steering current from a PFET-based cascoded current source. This embodiment, as in the case of the embodiment with transmit emphasis, is not in compliance with DVI specifications. A key benefit in this embodiment is that it offers enhanced output slew rates through the use of NFET current-steering switches. Output signals in this embodiment are referenced to ground, and therefore will require correspondingly designed receiver circuits at the far-end of the link. The signaling technique facilitated by this embodiment is identical to ground-referenced voltage swing (GRVS) signaling, and is well-suited for low-voltage systems.

Although specific embodiments are illustrated and described herein, any circuit arrangement configured to achieve the same purposes and advantages may be substituted in place of the specific embodiments disclosed. This disclosure is intended to cover any and all adaptations or variations of the embodiments of the invention provided herein. All the descriptions provided in the specification have been made in an illustrative sense and should in no manner be interpreted in any restrictive sense. The scope, of various embodiments of the invention whether described or not, includes any other applications in which the structures, concepts and methods of the invention may be applied. The scope of the various embodiments of the invention should therefore be determined with reference to the appended claims, along with the full range of equivalents to which such claims are entitled. Similarly, the abstract of this disclosure, provided in compliance with 37 CFR §1.72(b), is submitted with the understanding that it will not be interpreted to be limiting the scope or meaning of the claims made herein. While various concepts and methods of the invention are grouped together into a single ‘best-mode’ implementation in the detailed description, it should be appreciated that inventive subject matter lies in less than all features of any disclosed embodiment, and as the claims incorporated herein indicate, each claim is to viewed as standing on it's own as a preferred embodiment of the invention.

What is claimed is:

1. An output driver for differential signal output, comprising
a cascoded current source attached to a first stable voltage source, having a current-source transistor driven by a first input bias voltage in series with a cascode transistor driven by a second input reference voltage,
a pair of differential current-steering metal-oxide-semiconductor field-effect transistors with their drain terminals connecting together and to the cascoded current source, and source terminals providing differential output signals of the driver,
wherein signal voltage transitions at gate and source terminals of each differential current-steering metal-oxide-semiconductor field-effect transistor are in phase.

2. The apparatus of claim 1, with differential outputs connecting through signal pathways to termination elements attached to a second stable voltage source, employed to generate voltage swings across these terminating elements.

3. The apparatus of claim 2 where the second stable voltage reference and termination elements are part of another system not containing the driver apparatus.

4. The apparatus of claim 3 where the terminating elements are resistors matched to the characteristic impedance of the signal pathways.

5. The apparatus of claim 4, with p-type field-effect transistors employed as current-steering switches, n-type field effect transistors as cascode and current source transistors, and where the second stable voltage source is substantially higher in potential than the first stable voltage source.

6. The apparatus of claim 5 employed in DVI/HDMI compatible systems and communication links.

7. The apparatus of claim 6 where communication link lengths substantially exceed DVI/HDMI specifications.

8. The apparatus of claim 4, with n-type field-effect transistors employed as current-steering switches, p-type field effect transistors as cascode and current source transistors, and where the second stable voltage source is substantially lower in potential than the first stable voltage source.

9. The apparatus of claim 1, with one or more additional cascoded current sources connecting between the current-steering transistors and the first stable voltage source, employed for symbol-dependent drive current modulation.

10. The apparatus of claim 9 employed for de-emphasis signal equalization.

11. The apparatus of claim 9 employed for pre-emphasis signal equalization.

12. A method for output signal generation, comprising:
steering a current developed in a current source through one or more MOS field-effect transistors, whose source terminals provide output signals, by providing activating electrical signals to said MOS field-effect transistors.
wherein a miller coupling capacitance of the MOS field-effect transistor conveys a portion of its activating electrical signal energy to an output signal in phase with output voltage change, assisting output signal development.

13. The method of claim 12 where current flows through a MOS field-effect transistor from an output node to ground, and said MOS field-effect transistor is a p-type metal-oxide-semiconductor field-effect transistor.

14. The method of claim 12, where current source output impedance is enhanced by a simple or gain-boosted cascode device.

15. The method of claim 12, applied to a differential output signal pair for binary symbol transmission, where current is steered to one output signal or another based upon the binary symbol transmitted.

16. Electronic systems comprised of various integrated and discrete electronic circuits and devices that employ the apparatus of claim 1 in any embodiment.

17. Integrated or discrete output driver circuits that employ the method of claim 12.
